(19) United States
(12) Patent Application Publication
(10) Pub. No.: US 2019/0348582 A1
(43) Pub. Date: Nov. 14, 2019

(54) OPTOELECTRONIC PACKAGE

(71) Applicant: UNISTARS CORPORATION, Zhudong Township (TW)

(72) Inventor: TIEN-HAO HUANG, New Taipei City (TW)

(21) Appl. No.: 16/008,053

(22) Filed: Jun. 14, 2018

(30) Foreign Application Priority Data
May 10, 2018 (TW) 107115954

(51) Int. Cl. H01L 33/58; H01L 33/08; H01L 33/62; H01L 33/50; H01L 33/52

(52) U.S. Cl. CPC H01L 33/58; H01L 33/08; H01L 33/52; H01L 33/507; H01L 33/62

(57) ABSTRACT

An optoelectronic package comprises a carrier, at least one light-emitting chip, a light scattering layer and a light-shielding pattern. The carrier comprises a substrate and a wiring layer formed on the substrate. The light-emitting chip used for emitting light is mounted on the substrate and electrically connected to the wiring layer. The light scattering layer covers the substrate and the wiring layer and encapsulates the light-emitting chip. The light-shielding pattern is formed on the light scattering layer and used for blocking a part of the light.

### FIELD OF THE INVENTION

The present invention relates to a semiconductor package and more particularly to an optoelectronic package having a light-shielding pattern.

### BACKGROUND OF THE INVENTION

A light emitting diode (LED) is a semiconductor package and has a diode die that can emit light. The diode die is usually made by dicing a wafer. In general, most light emitting diodes have a relatively small viewing angle, so that the light emitting diode emits light concentratedly, thereby causing difficulty for the light emitting diode to emit light uniformly. Therefore, at present, it is difficult for the light emitting diode to directly emit light uniformly, and a secondary optical element such as a diffuser must be additionally mounted to achieve uniform light emitting effect for the light emitting diode.

### SUMMARY OF THE INVENTION

The present invention provides an optoelectronic package including a light scattering layer which can facilitate the light to be emitted uniformly.

The optoelectronic package provided by the present invention includes a carrier, at least one light-emitting chip, a light scattering layer and a light-shielding pattern. The carrier includes a substrate and a wiring layer formed on the substrate. The light-emitting chip is mounted on the substrate and electrically connected to the wiring layer, wherein the light-emitting chip is used for emitting light. The light scattering layer covers the substrate and the wiring layer and encapsulates the light-emitting chip, wherein the light scattering layer is located in a transmission path of the light. The light-shielding pattern is formed on the light scattering layer and used for blocking a part of the light.

In an embodiment of the present invention, a quantity of the light-emitting chip is plurality.

In an embodiment of the present invention, the light-emitting chips are arranged in an array.

In an embodiment of the present invention, the light scattering layer includes a light transmitting layer and a diffusion layer. The light transmitting layer covers the substrate and the wiring layer and encapsulates the light-emitting chip. The diffusion layer covers the light transmitting layer and is used for diverging the light, wherein the light transmitting layer is formed between the carrier and the diffusion layer, and is located in the transmission path of the light.

In an embodiment of the invention, the light-emitting chip has a light-emitting surface, and the light transmitting layer covers and contacts the light-emitting surface.

In an embodiment of the present invention, a side of the light transmitting layer and a side of the diffusion layer are flush with each other.

In an embodiment of the present invention, the diffusion layer contains diffusion particles or a fluorescent material excited by the light.

In an embodiment of the invention, a refractive index of the diffusion layer is larger than a refractive index of the light transmitting layer.

In an embodiment of the present invention, the substrate includes a metal plate and an insulating layer. The insulating layer is formed on the metal plate, and between the metal plate and the wiring layer.

In an embodiment of the invention, the optoelectronic package further includes a protective layer, wherein the protective layer is formed above the light scattering layer and covers the light-shielding pattern.

Based on the above, by using the light scattering layer, the optoelectronic package can directly and uniformly emit light without additionally mounting a secondary optical element (such as a diffuser). As a result, the time and money spent on mounting the secondary optical element can be saved, thereby to reduce production costs and improve throughput.

The structural features and the technical means adopted by the present invention to achieve the above and other objects can be best understood by referring to the following detailed description of the embodiments and the accompanying drawings. However, the detailed description and the accompanying drawings are only used to explain and illustrate the present invention rather than as limitative of the appended claims of the present invention.

### BRIEF DESCRIPTION OF THE DRAWINGS

The present invention will become more readily apparent to those ordinarily skilled in the art after reviewing the following detailed description and accompanying drawings, in which:

FIG. 1 is a schematic cross-sectional view of an optoelectronic package according to an embodiment of the invention;

FIG. 2 is a schematic top view of the optoelectronic package in FIG. 1; and

FIG. 3 is a schematic cross-sectional view of the optoelectronic package in FIG. 2 after removing a light scattering layer, a light-shielding pattern and a protective layer.

### DETAILED DESCRIPTION OF EMBODIMENTS

Hereinafter, the present invention will be described in detail with drawings illustrating various embodiments of the present invention. However, the concept of the present invention may be embodied in many different forms and should not be construed as limitative of the exemplary embodiments set forth herein.

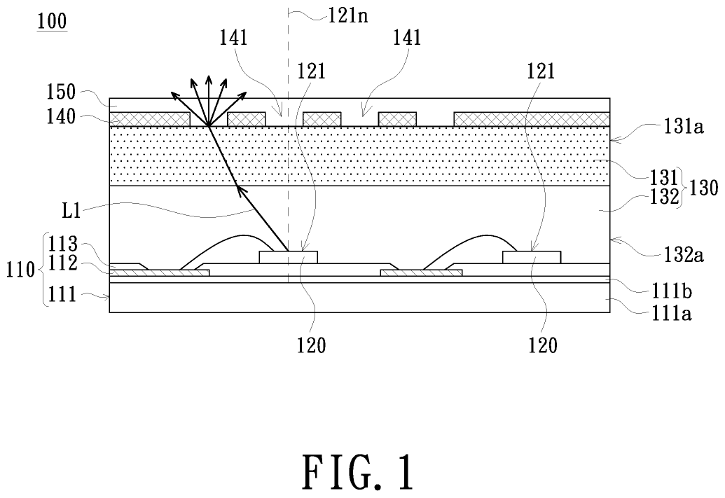

FIG. 1 is a schematic cross-sectional view of an optoelectronic package according to an embodiment of the invention. Referring to FIG. 1, an optoelectronic package 100 includes a carrier 110 and at least one light-emitting chip 120. The carrier 110 includes a substrate 111 and a wiring layer 112 formed on the substrate 111. The light-emitting chip 120 is mounted on the substrate 111 and electrically connected to the wiring layer 112, where the light-emitting chip 120 has a light-emitting surface 121 and can emit light L1 from the light-emitting surface 121 thereof. In the embodiment shown in FIG. 1, the optoelectronic package 100 includes a plurality of light-emitting chips 120, and the light-emitting chips 120 are mounted on the substrate 111. However, in other embodiments, the optoelectronic package 100 can include only one light-emitting chip 120. Therefore, the quantity of the light-emitting chips 120 shown in FIG. 1 is merely an example, and the quantity of the light-emitting chip 120 included in the optoelectronic package 100 is not limited thereto.

In the embodiment, the light-emitting chip 120 may be an unpackaged diode die, and the optoelectronic package 100 can be a semiconductor package. In other words, the optoelectronic package 100 may be a light emitting diode (LED) and also be a discrete component. In other embodiments, the light-emitting chip 120 may also be a packaged semiconductor package and include a carrier and a diode die mounted on the carrier. Accordingly, the optoelectronic package 100 can also include at least one packaged semiconductor package.

In addition, in the embodiment shown in FIG. 1, the light-emitting chips 120 are mounted on the carrier 110 by wire-bonding. But in other embodiments, the light-emitting chips 120 can also be mounted on the carrier 110 by other means, such as flip-chip. Therefore, mounting practical situation of the light-emitting chip 120 on the carrier 110 is not limited to only wire bonding alone.

The carrier 110 is a metal base board. Taking FIG. 1 as an example, the substrate 111 includes a metal plate 111a and an insulating layer 111b. The insulating layer 111b is not only formed on the metal plate 111a, but also between the metal plate 111a and the wiring layer 112. In one embodiment, the carrier 110 may be an aluminum base board, where the metal plate 111a may be an aluminum plate, and the wiring layer 112 may be a copper layer. The material of the insulating layer 111b may be aluminum oxide, and the insulating layer 111b can be formed by oxidizing aluminum on the surface of the metal plate 111a. Therefore, the insulating layer 111b can be a dense oxide layer and keep the wiring layer 112 and the metal plate 111a electrically insulated from each other.

In the embodiment shown in FIG. 1, the carrier 110 may further include a solder mask 113 formed on the substrate 111. The type of the solder mask 113 may be Solder Mask Defined (SMD), so that the solder mask 113 covers the wiring layer 112 partially and contacts the wiring layer 112. However, in other embodiments, the type of the solder mask 113 may also be Non-Solder Mask Defined (NSMD). In other words, the solder mask 113 in the other embodiments does not cover and not contact the wiring layer 112. The color of the solder mask 113 may be white to cause the solder mask 113 to reflect the light L1, thereby helping improve the brightness of the optoelectronic package 100. In addition, it is noted that the solder mask 113 shown in FIG. 1 is for illustration only. In other embodiments, the carrier 110 include no solder mask 113. That is, the carrier 110 is not limited to including the solder mask 113.

The carrier 110 shown in FIG. 1 is a single-sided wiring board, but the carrier 110 in other embodiments may be a double-sided wiring board. That is, the carrier 110 can include two wiring layers 112, and the substrate 111 is disposed between the two wiring layers 112. The two wiring layers 112 can be electrically connected to each other by a conductive through hole (not labelled). The conductive through hole can be made by performing the following steps. First, a through hole is formed in the substrate 111 by mechanical drilling. Then, an insulating material is inserted into the through hole, and the insulating material is, for example, a resin. Afterwards, a narrow through hole with a smaller diameter is formed in the insulating material by mechanical drilling or laser drilling. Then, a plating through hole (PTH) is performed to the narrow through hole to complete the conductive through hole.

It is noted that in other embodiments, the carrier 110 can also be a printed wiring board (PWB), for example, a metal core circuit board or a multilayer wiring board. That is, the substrate 111 in other embodiments can include a resin layer or a ceramic layer. Therefore, the metal base board is only one example of the carrier 110, and the carrier 110 is not limited only to a metal base board.

The optoelectronic package 100 further includes a light scattering layer 130. The light scattering layer 130 covers the substrate 111, the wiring layer 112 and the solder mask 113, and encapsulates the light-emitting chip 120. The light scattering layer 130 can contact the light-emitting chip 120. The light scattering layer 130 covers the light-emitting surface 121 of the light-emitting chip 120, so that the light scattering layer 130 is located in the transmission path of the light L1. The light scattering layer 130 shown in FIG. 1 has a double-layered structure and includes a diffusion layer 131 and a light transmitting layer 132. The light transmitting layer 132 covers the substrate 111 and the wiring layer 112 and encapsulates the light-emitting chip 120, so that the light transmitting layer 132 can cover and contact the light-emitting surface 121 of the light-emitting chip 120.

The diffusion layer 131 covers the light transmitting layer 132 formed between the carrier 110 and the diffusion layer 131, so that the diffusion layer 131 is also located in the transmission path of the light L1. After the light L1 exits from the light-emitting surface 121 of the light-emitting chip 120, it enters the light transmitting layer 132 and the diffusion layer 131 sequentially. The diffusion layer 131 can include a plurality of (light) diffusion particles (not shown) and a transparent medium (not shown). The (light) diffusion particles are dispersed in the transparent medium, and the transparent medium is, for example, polysiloxane. These diffusion particles can scatter the light L1, so that the diffusion layer 131 can diverge the light L1. Alternatively, in other embodiments, the diffusion layer 131 can also contain a fluorescent material excited by the light to emit fluorescent light. In other words, the diffusion layer 131 can contain the diffusion particles or the fluorescent material.

In this embodiment, a refractive index of the diffusion layer 131 can be larger than a refractive index of the light transmitting layer 132, so that a traveling direction of the light L1 is closer to a normal 121n of the light-emitting surface 121 after the light L1 passes through the boundary between the diffusion layer 131 and the light transmitting layer 132, thereby facilitating the light L1 to enter the diffusion layer 131 concentratedly. As a result, more of the light L1 can enter the diffusion layer 131, so that the diffusion layer 131 can diverge more of the light L1, thereby improving the brightness of the optoelectronic package 100.

It is noted that the light L1 in FIG. 1 appears to be scattered only at the upper surface of the diffusion layer 131. However, in practical situations, since the diffusion layer 131 contains a plurality of diffusion particles, the light L1 is not only scattered at the upper surface of the diffusion layer 131, but also scattered within the diffusion layer 131 by the diffusion particles. The light L1 scattered at the upper surface of the diffusion layer 131 shown in FIG. 1 is only to describe that the light L1 passing through the diffusion layer 131 exits in multiple directions. It does not interpret the light L1 as being only scattering at the upper surface of the diffusion layer 131.

It is worth mentioning that in the embodiment shown in FIG. 1, the light scattering layer 130 has the double-layer structure because it includes the diffusion layer 131 and the light transmitting layer 132, but in other embodiments, the light scattering layer 130 can have a single-layer structure or a multilayer structure having more than two layers. For example, the light scattering layer 130 in FIG. 1 can include only the diffusion layer 131, but no light transmitting layer 132 in other embodiments. That is, the light scattering layer 130 in other embodiments may be the diffusion layer 131. Therefore, the light scattering layer 130 shown in FIG. 1 is for illustration only. The light scattering layer 130 is not limited to having only the double-layer structure. Additionally, in the manufacture of the optoelectronic package 100, a plurality of the optoelectronic packages 100 can be formed by dicing a package panel, so that a side 132a of the light transmitting layer 132 and a side 131a of the diffusion layer 131 are flush with each other, as shown in FIG. 1.

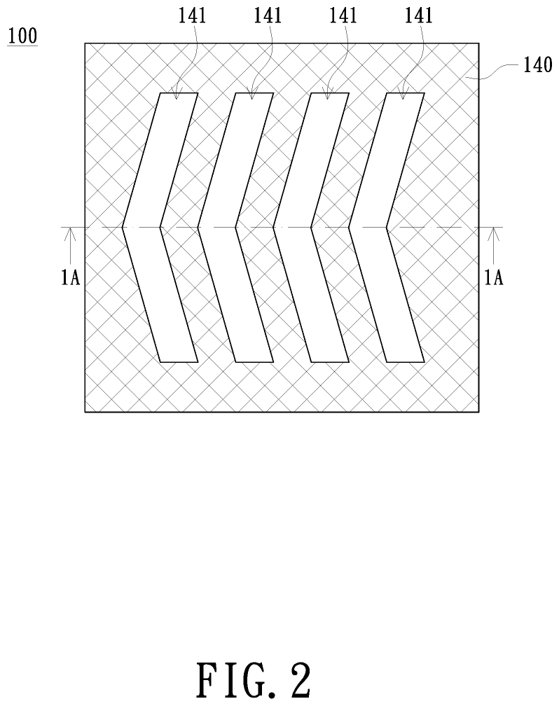

FIG. 2 is a schematic top view of the optoelectronic package in FIG. 1, where the cross-sectional schematic diagram shown in FIG. 1 is sectioned along a line 1A-1A in FIG. 2. Referring to FIG. 1 and FIG. 2, the optoelectronic package 100 further includes a light-shielding pattern 140 which is formed on the light scattering layer 130 and used for blocking a part of the light L1. Specifically, the light-shielding pattern 140 is opaque and has a plurality of openings 141. When the light L1 enters the light-shielding pattern 140, a part of the light L1 passes through the openings 141, and other parts of the light L1 are blocked by the light-shielding pattern 140. That is, the light-shielding pattern 140 can block a part of the light L1. In addition, the light-shielding pattern 140 can be made of ink and formed by spraying or brushing thereof on the light scattering layer 130.

In the embodiment shown in FIG. 2, the shape of each of the openings 141 is a chevron or V-shaped. When the light-emitting chip 120 emits the light L1, the optoelectronic package 100 will show illuminated chevrons as shown in FIG. 2. The illuminated chevrons shown on the optoelectronic package 100 can be used as an indication. For example, the optoelectronic package 100 shown in FIG. 2 can be used for making a directional light of the vehicle to indicate the steering (or turn signal) of the vehicle. Alternatively, the optoelectronic package 100 can also be used for making an emergency indicator light to indicate the direction of escape.

The optoelectronic package 100 can further include a protective layer 150 which is formed above the light scattering layer 130 and covers the light-shielding pattern 140 to protect the light-shielding pattern 140. The protective layer 150 is a transparent layer, so the light L1 can penetrate the protective layer 150. In addition, it is noted that in the embodiment shown in FIG. 1, the optoelectronic package 100 includes the protective layer 150. However, in other embodiments, the optoelectronic package 100 does not include the protective layer 150. Therefore, the protective layer 150 shown in FIG. 1 is only for illustration. The optoelectronic package 100 is not limited to including the protective layer 150.

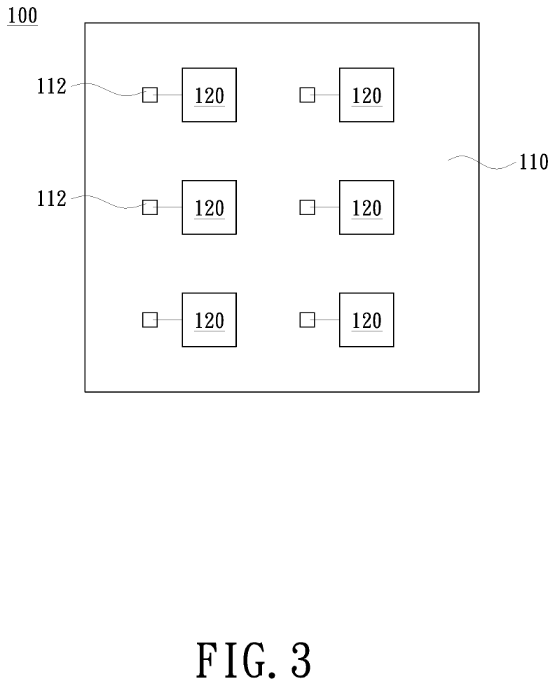

FIG. 3 is a schematic cross-sectional view of the optoelectronic package in FIG. 2 after removing the light scattering layer, the light-shielding pattern and the protective layer. Referring to FIG. 3, in this embodiment, the light-emitting chips 120 can be arranged in an array, as shown in FIG. 3. In other words, the light-emitting chips 120 can be regularly mounted on the carrier 110 to improve the luminous uniformity of the optoelectronic package 100. However, even if the light-emitting chips 120 are arranged in a manner other than the illustrated array arrangement, for example, randomly arranged, the light scattering layer 130 still can diffuse the light L1 to facilitate the optoelectronic package 100 to emit light uniformly. In addition, the light-emitting chips 120 can also be mounted on the carrier 110 corresponding to the openings 141 of the light-shielding pattern 140. In other words, the light-emitting chips 120 can overlap with the openings 141 of the light-shielding pattern 140 to reduce an amount of the light L1 blocked by the light-shielding pattern 140, thereby improving the utilization rate of the light L1.

In summary, the optoelectronic package in at least one of the embodiments of the present invention can directly and uniformly emit light without any secondary optical element. Therefore, it is not necessary for the optoelectronic package to additionally mount an external secondary optical element (e.g. a diffuser) one by one, individually. Compared with the conventional light emitting diodes equipped with secondary optical elements, the present invention can save the time and money spent on the mounting of secondary optical elements, thereby helping to reduce production costs and improving throughput. Moreover, since the optoelectronic package does not require additional mounting of secondary optical elements, the light emitted from the optoelectronic package does not penetrate the secondary optical element. Therefore, the optoelectronic package can have better luminous efficiency than that of the conventional light emitting diodes.

Note that the specifications relating to the above embodiments should be construed as exemplary rather than as limitative of the present invention, with many variations and modifications being readily attainable by a person of average skill in the art without departing from the spirit or scope thereof as defined by the appended claims and their legal equivalents.

1. An optoelectronic package comprising:
a carrier comprising a substrate and a wiring layer formed on the substrate;
at least one light-emitting chip mounted on the substrate and electrically connected to the wiring layer;
a light scattering layer covering the substrate and the wiring layer and encapsulating the light-emitting chip, comprises:
a light transmitting layer covering the substrate and the wiring layer and encapsulating the light-emitting chip;
a diffusion layer covering the light transmitting layer, wherein the light transmitting layer is formed between the carrier and the diffusion layer, and is located in a transmission path of the light; and
a light-shielding pattern formed on the light scattering layer;
wherein the light scattering layer is located in the transmission path of a light;
wherein the light is emitting from the at least one light-emitting chip, while a part of the light is blocked by the light-shielding pattern, and a remaining part of the light is transmitting through the light scattering layer to the outside.

2. The optoelectronic package according to claim 1, wherein a quantity of the light-emitting chip is plurality.

3. The optoelectronic package according to claim 2, wherein the light-emitting chips are arranged in an array.

4. (canceled)

5. The optoelectronic package according to claim 1, wherein the light-emitting chip has a light-emitting surface, and the light transmitting layer covers and contacts the light-emitting surface of the light-emitting chip.

6. The optoelectronic package according to claim 1, wherein a side of the light transmitting layer and a side of the diffusion layer are flush with each other.

7. The optoelectronic package according to claim 1, wherein the diffusion layer contains a plurality of diffusion particles or a fluorescent material excited by the light.

8. The optoelectronic package according to claim 1, wherein a refractive index of the diffusion layer is larger than a refractive index of the light transmitting layer.

9. The optoelectronic package according to claim 1, wherein the substrate comprises:
a metal plate; and
an insulating layer formed on the metal plate, and between the metal plate and the wiring layer.

10. The optoelectronic package according to claim 1, further comprising a protective layer, wherein the protective layer is formed above the light scattering layer and covers the light-shielding pattern.
